(19) United States
(12) Patent Application Publication
(10) Pub. No.: US 2025/0351700 A1
(43) Pub. Date: Nov. 13, 2025

(54) Defect Reduction Through Scheme Of Conductive Pad Layer And Capping Layer

(71) Applicant: Taiwan Semiconductor Manufacturing Company, Ltd., Hsin-Chu (TW)

(72) Inventors: Ching Ju Yang, Hsinchu (TW); Yao-Wen Chang, Hsinchu (TW); Chih-Chung Lai, Hsinchu County (TW)

(21) Appl. No.: 19/277,097

(22) Filed: Jul. 22, 2025

Related U.S. Application Data
(62) Division of application No. 17/890,883, filed on Aug. 18, 2022.
(60) Provisional application No. 63/333,824, filed on Apr. 22, 2022.

(51) Int. Cl. H10K 59/179; H10K 71/00

(52) U.S. Cl. CPC H10K 59/1795; H10K 71/00

(57) ABSTRACT

An interconnect structure includes at least a first interconnect element and a second interconnect element. A conductive pad layer is disposed over, and electrically coupled to, the first interconnect element. A capping layer is disposed over the conductive pad layer. The capping layer includes titanium nitride. A dielectric layer is disposed over the capping layer. A conductive contact extends vertically through at least a first portion of the dielectric layer and the capping layer. The conductive contact is coupled to the first interconnect element through the conductive pad layer. A conductive via extends vertically through at least a second portion of the dielectric layer. The conductive via is coupled to the second interconnect element.

### PRIORITY DATA

This present application is a Divisional Application of U.S. patent application Ser. No. 17/890,883 filed on Aug. 18, 2022, entitled “Defect Reduction Through Scheme Of Conductive Pad Layer And Capping Layer,” which claims benefit of Provisional U.S. Application 63/333,824, filed on Apr. 22, 2022, entitled “Yield Enhancement By Conductive Pad Scheme”, the disclosures of each which are hereby incorporated by reference in their respective entireties.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

However, as the scaling down process continues, it has become more difficult to fabricate IC device without performance degradations. For example, as device sizes become smaller, alignment between various layers is harder to achieve. To ensure accurate alignment, it may be desirable to reduce a reflectivity of conductive pads of an IC device. Unfortunately, conventional techniques of reducing the reflectivity of conductive pads have led to device defects such as hillocks. As a result, device yield and/or device performance may worsen.

Therefore, although existing semiconductor devices and their method of fabrication have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a three-dimensional perspective view of a FinFET device.

FIG. 1B illustrates a top view of a FinFET device.

FIG. 1C illustrates a three-dimensional perspective view of a multi-channel gate-all-around (GAA) device.

FIGS. 2-21 illustrate a series of cross-sectional views of a semiconductor device at various stages of fabrication according to embodiments of the present disclosure.

FIG. 22 illustrates an integrated circuit fabrication system according to various aspects of the present disclosure.

FIG. 23 is a flowchart illustrating a method of fabricating a semiconductor device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to configuring material compositions of a conductive pad and a capping layer, such that the resulting combination thereof can achieve low reflectivity without creating defects such as hillock issues. For example, the present disclosure may form a conductive pad having aluminum that is doped with silicon or aluminum that is doped with ruthenium. The present disclosure may also form a capping layer that contains a conductive material, such as titanium nitride, over the conductive pad. Such a configuration of the conductive pad and the capping layer formed thereon can achieve low reflectivity, which helps with alignment. In addition, such a configuration of the conductive pad and the capping layer reduces the likelihood of generating defects. For example, defects such as hillocks may be substantially reduced or eliminated.

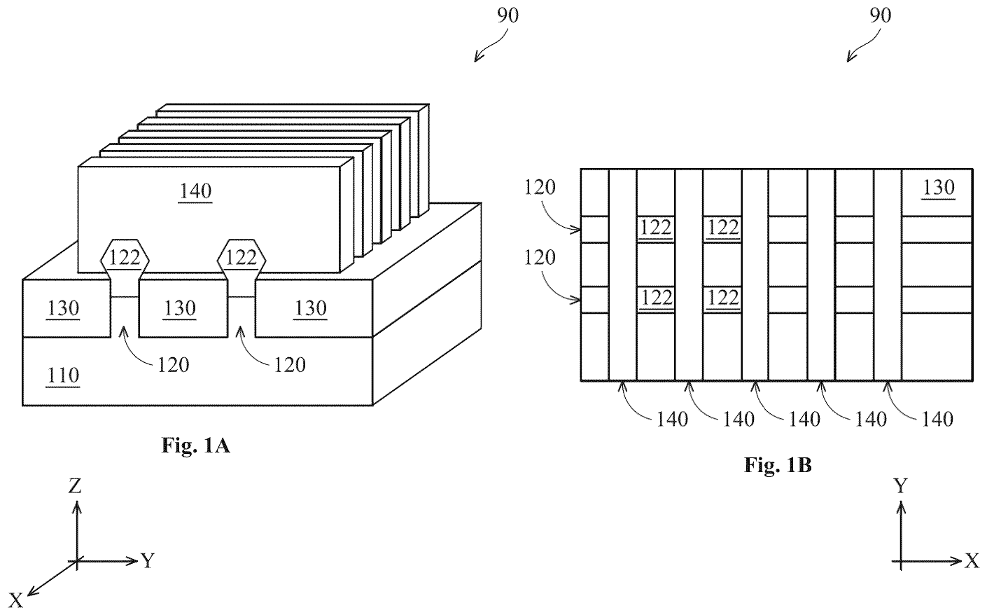

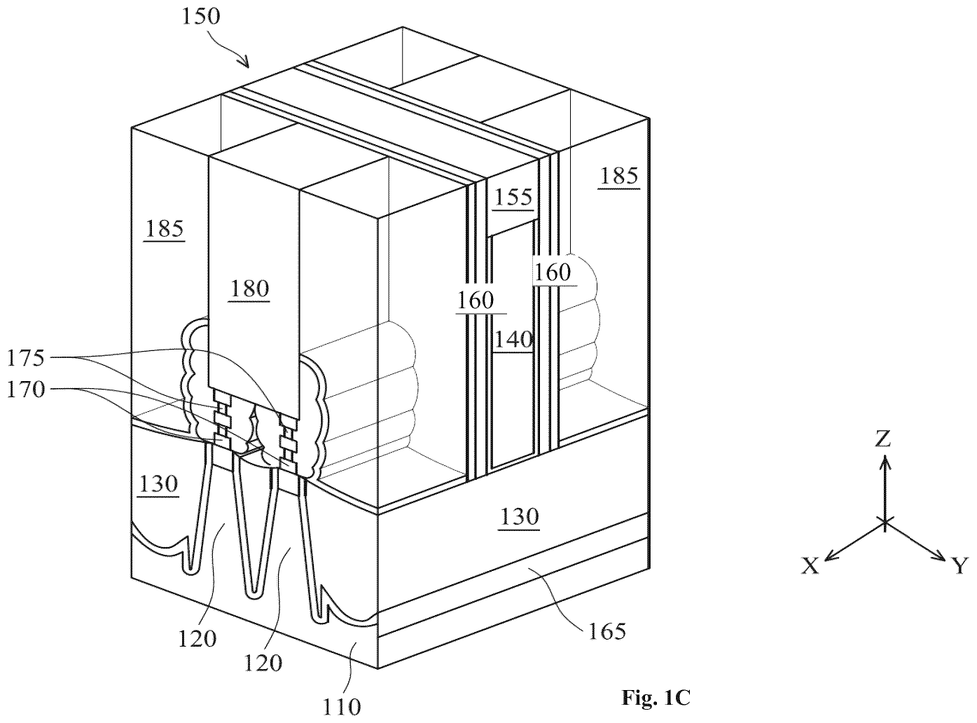

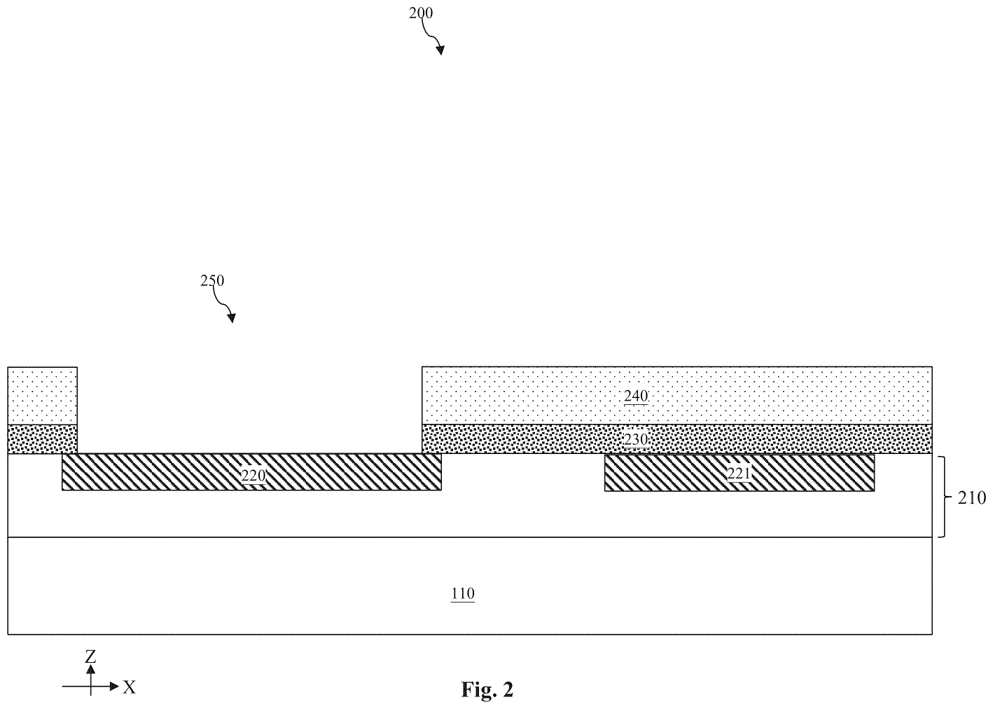

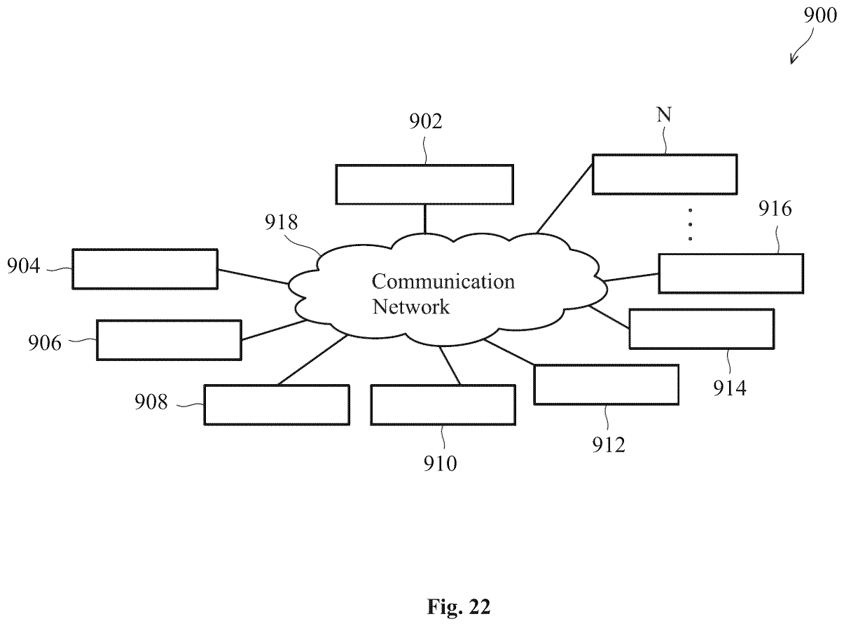

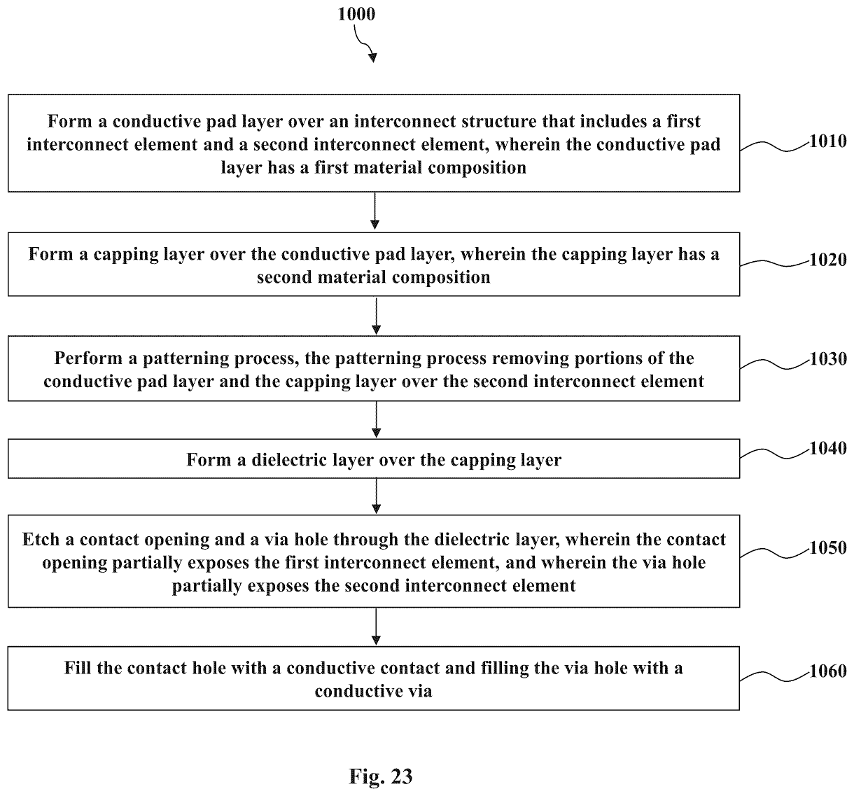

The various aspects of the present disclosure will now be discussed below with reference to FIGS. 1A, 1B, 1C, and 2-23. In more detail, FIGS. 1A-B illustrate an example FinFET device, and FIG. 1C illustrates an example GAA device. FIGS. 2-21 illustrate cross-sectional side views of an IC device at various stages of fabrication according to embodiments of the present disclosure. FIG. 22 illustrates a semiconductor fabrication system. FIG. 23 illustrates a flowchart of a method of fabricating an IC device according to various aspects of the present disclosure.

Referring now to FIGS. 1A and 1B, a three-dimensional perspective view and a top view of a portion of an Integrated Circuit (IC) device 90 are illustrated, respectively. The IC device 90 is implemented using field-effect transistors (FETs) such as three-dimensional fin-line FETs (FinFETs). FinFET devices have semiconductor fin structures that protrude vertically out of a substrate. The fin structures are active regions, from which source/drain region(s) and/or channel regions are formed. Source/drain region(s) may refer to a source or a drain, individually or collectively dependent upon the context. A source/drain region may also refer to a region that provides a source and/or drain for multiple devices. The gate structures partially wrap around the fin structures. In recent years, FinFET devices have gained popularity due to their enhanced performance compared to conventional planar transistors.

As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 may include elongated fin-like structures that protrude upwardly out of the substrate 110. As such, the active regions 120 may be interchangeably referred to as fin structures 120 or fins 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain components 122 formed over the fin structures 120. The source/drain components 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. In other words, the gate structures 140 each wrap around a plurality of fin structures 120. The gate structures 140 may be dummy gate structures (e.g., containing an oxide gate dielectric and a polysilicon gate electrode), or they may be High-k metal gate (HKMG) structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIGS. 1A-1B, multiple fin structures 120 are each oriented lengthwise along the X-direction, and multiple gate structure 140 are each oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a three-dimensional perspective view of an example multi-channel gate-all-around (GAA) device 150. GAA devices have multiple elongated nano-structure channels that may be implemented as nano-tubes, nano-sheets, or nano-wires. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A mask 155 is located over the gate structure 140, and gate spacers 160 are located on sidewalls of the gate structure 140. A capping layer 165 is formed over the fin structures 120 to protect the fin structures 120 from oxidation during the forming of the isolation structures 130.

A plurality of nano-structures 170 is disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each stack of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180. The ILD 185 may be referred to as an ILD0 layer. In some embodiments, the ILD 185 may include silicon oxide, silicon nitride, or a low-k dielectric material.

The FinFET devices of FIGS. 1A-1B and the GAA devices of FIG. 1C may be utilized to implement electrical circuitries having various functionalities, such as memory devices (e.g., static random access memory (SRAM) devices), logic circuitries, application specific integrated circuit (ASIC) devices, radio frequency (RF) circuitries, drivers, micro-controllers, central processing units (CPUs), image sensors, etc., as non-limiting examples.

FIGS. 2-21 illustrate diagrammatic fragmentary cross-sectional views of a portion of an IC device 200 at various stages of fabrication according to various embodiments of the present disclosure. In more detail, FIGS. 2-21 illustrate the cross-sectional views along an X-Z plane, and as such, FIGS. 2-21 may be referred to as X-cuts.

As shown in FIG. 2, the IC device 200 includes the substrate 110 discussed above, which may comprise an elementary (single element) semiconductor, a compound semiconductor, an alloy semiconductor, and/or other suitable materials. Electrical circuitries may be formed in (or over) the substrate 110. The electrical circuitries may be implemented at least in part using transistors, such as the FinFET transistors shown in FIGS. 1B-1C and/or the GAA transistors shown in FIG. 1C. For reasons of simplicity, the details of the electrical circuitries are not illustrated in FIG. 2 or the subsequent figures.

A multi-layer interconnect structure 210 may be formed over the substrate 110. The multi-layer interconnect structure 210 may include a plurality of interconnect layers that include interconnect elements such as metal lines and conductive vias. As a simple example, an interconnect element 220 and an interconnect element 221 are illustrated herein as a part of the multi-layer interconnect structure 210. In some embodiments, the interconnect elements 220 and 221 include metal lines of a topmost metal layer of the interconnect structure 210. The interconnect elements 220 and 221 have a conductive material composition. In some embodiments, the interconnect elements 220 and 221 each include copper (Cu). In other embodiments, the interconnect elements 220 and 221 may include conductive materials such as aluminum, cobalt, ruthenium, tungsten, titanium, or combinations thereof.

An etch stop layer 230 is formed over the interconnect structure 210, including over the interconnect elements 220-221. The etch stop layer 230 may be formed using a chemical vapor deposition (CVD) process, a physical vapor deposition (PVD) process, an atomic layer deposition (ALD) process, or combinations thereof. In some embodiments, the etch stop layer 230 includes silicon nitride (SiN). In some embodiments, the etch stop layer 230 may be configured to have a thickness in a range between about 1 kilo-angstroms and about 2 kilo-angstroms.

A passivation layer 240 is formed over the etch stop layer 230. The passivation layer 240 may also be formed by a CVD process, a PVD process, an ALD process, or combinations thereof. In some embodiments, the passivation layer 240 includes silicon oxide (SiO₂).

One or more etching processes may be performed to form an opening 250 that extends vertically through the passivation layer 240 and the etch stop layer 230. In some embodiments, the one or more etching processes include a wet etching process. In other embodiments, the one or more etching processes include a dry etching process. The opening 250 exposes at least a portion of an upper surface of the interconnect element 220.

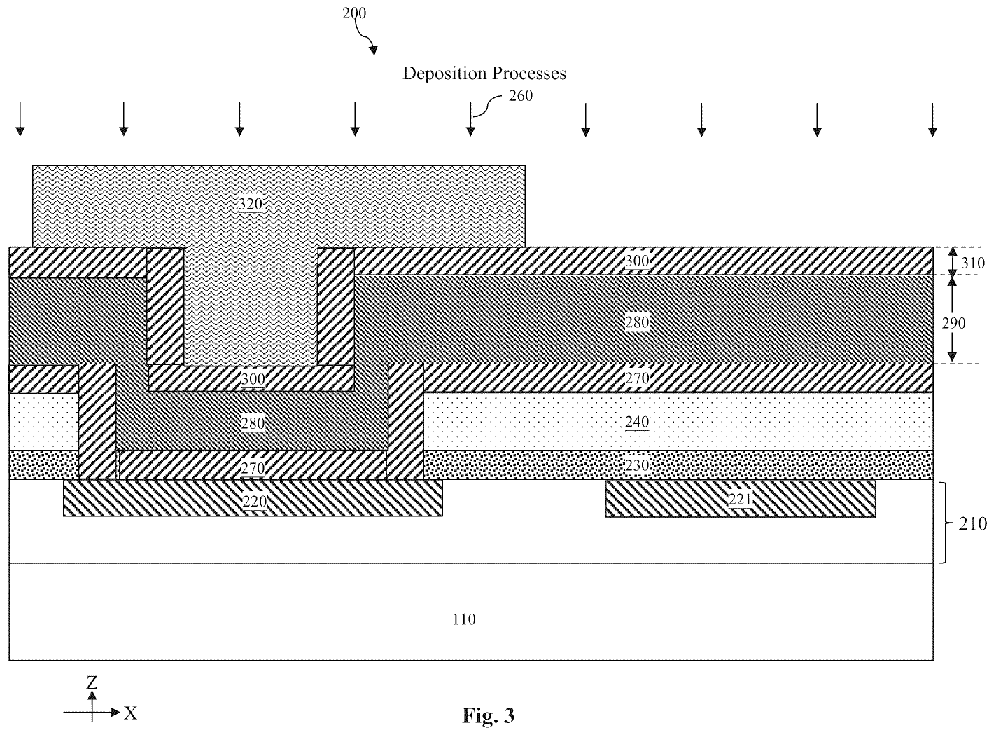

Referring now to FIG. 3, a plurality of deposition processes 260 may be performed to the IC device 200. In some embodiments, the deposition processes 260 may include one or more CVD processes, one or more PVD processes, one or more ALD processes, or combinations thereof. One of the deposition processes 260 is performed to form a diffusion barrier layer 270 over the passivation layer 240. The diffusion barrier layer 270 partially fills the opening 250 and is also formed on the exposed upper surface of the interconnect element 220, as well as on the sidewalls of the etch stop layer 230 and the passivation layer 240. A portion of the diffusion barrier layer 270 is also formed over the upper surface of the passivation layer 240. In some embodiments, the diffusion barrier layer 270 includes tantalum nitride (TaN), tantalum (Ta), or titanium nitride (TiN).

Another one of the deposition processes 260 (e.g., a PVD process or a CVD process) forms a conductive pad layer 280 over the diffusion barrier layer 270. In some embodiments, the conductive pad layer 280 includes aluminum (Al) that is doped with copper. In these embodiments, the surface roughness of the conductive pad layer 280 may be configured to have a high roughness (e.g., having a topography variation of greater than about 10 nanometers), or a low roughness (e.g., having a topography variation of less than about 10 nanometers). In another embodiment, the conductive pad layer 280 includes aluminum that is doped with silicon (Si). In yet another embodiment, the conductive pad layer 280 includes aluminum that is doped with ruthenium (Ru). In each of these embodiments, a content of the copper, silicon, or ruthenium in the conductive pad layer 280 is in a range between about 0.1% and about 0.5%.

In the embodiments where the conductive pad layer 280 has a material composition that is aluminum doped with silicon or aluminum doped with ruthenium, its thermal stability is improved over conventional materials used to implement the conductive pad layer 280. As a result of the thermal stability, defects such as hillocks (e.g., protruding bumps or other excessively uneven topography variations) are less likely to occur. In addition, the conductive pad layer 280 of these embodiments (e.g., having has the material composition that is aluminum doped with silicon or aluminum doped with ruthenium) has a lower reflectivity than conventional materials used to implement the conductive pad layer 280. The lower reflectivity makes it easier to achieve accurate alignment (e.g., alignment between alignment marks or registration marks) in various fabrication processes.

The conductive pad layer 280 is also formed to have a thickness 290 (measured in the Z-direction). The value of the thickness 290 may be configured by tuning the process parameters of the deposition process 260 that is used to deposit the conductive pad layer 280. For example, a deposition process time may be lengthened or shortened to adjust the value of the thickness 290. In some embodiments, a value of the thickness 290 is in a range between about 5 kilo-angstroms and about 10 kilo-angstroms. The above range is not randomly chosen but rather specifically configured to achieve a low reflectivity while minimizing the likelihood of generating defects such as hillocks.

Yet another one of the deposition processes 260 (e.g., an ALD process, a PVD process, or a CVD process) forms a conductive capping layer 300 over the conductive pad layer 280. In some embodiments, the conductive capping layer 300 includes a titanium-containing material, for example, titanium nitride (TiN). In other embodiments, the capping layer 300 may include oxygen-doped titanium nitride. According to various aspects of the present disclosure, the deposition process 260 used to form the conductive capping layer 300 is performed at a room temperature (e.g., between about 20 degrees Celsius and about 30 degrees Celsius). Such a low deposition temperature is beneficial, since defects such as hillocks are unlikely to form in a low temperature environment. As such, the conductive capping layer 300 (and/or the conductive pad layer 280) is less likely to have defects such as hillocks. In comparison, conventional fabrication processes may form capping layers at high process temperatures (e.g., around 400 degrees Celsius), which leads to hillocks for devices fabricated using conventional fabrication processes.

The conductive capping layer 300 is also formed to have a thickness 310 (measured in the Z-direction). The value of the thickness 310 may be configured by tuning the process parameters of the deposition process 260 that is used to deposit the conductive capping layer 300. For example, a deposition process time may be lengthened or shortened to adjust the value of the thickness 310. In some embodiments, a value of the thickness 310 is in a range between about 300 kilo-angstroms and about 1000 kilo-angstroms (note that FIG. 3 is not drawn to scale). The above range is not randomly chosen but rather specifically configured to achieve a low reflectivity while minimizing the likelihood of generating defects such as hillocks.

A patterned photoresist layer 320 is formed over the conductive capping layer 300 in a photolithography process. The photolithography process may include forming a photoresist film overlying the conductive capping layer 300, exposing the photoresist film to a pattern, performing post-exposure bake processes, and developing the photoresist to form the patterned photoresist layer. Note that the patterned photoresist layer 320 is formed over the portion of the interconnect structure 210 that contains the interconnect element 220, but not over the portion of the interconnect structure 210 that contains the interconnect element 221.

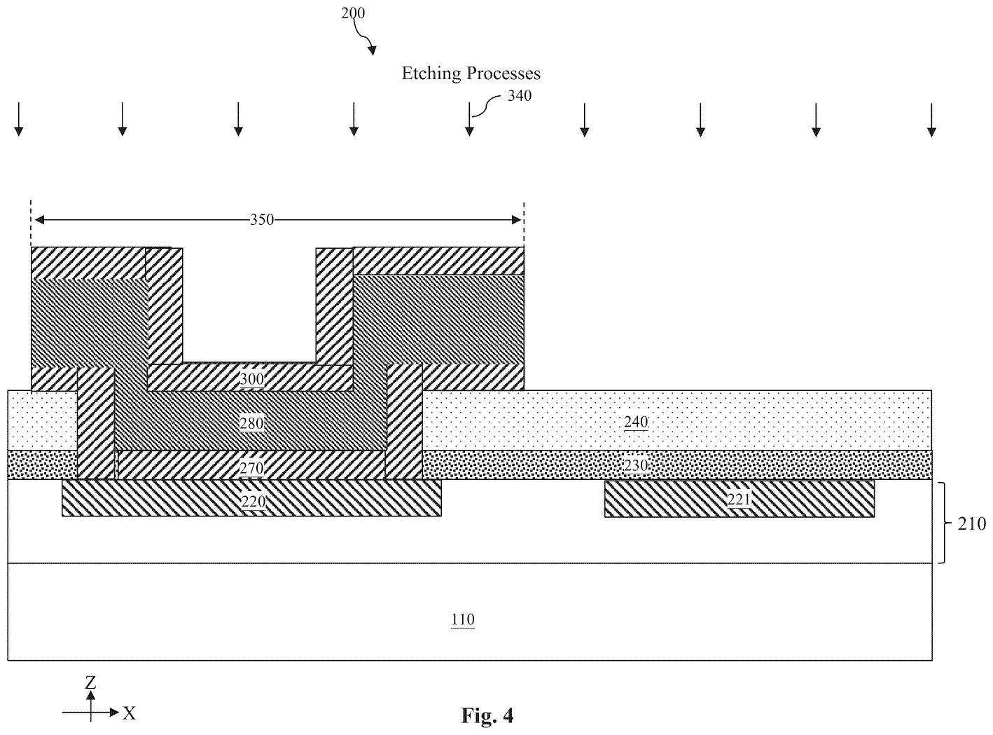

Referring now to FIG. 4, one or more etching processes 340 are performed to the IC device 200. The one or more etching processes 340 are performed to remove portions of the conductive capping layer 300, portions of the conductive pad layer 280, and portions of the diffusion barrier layer 270, while the patterned photoresist layer 320 serves as a protective mask to protect the layers therebelow from being etched. In some embodiments, the one or more etching processes 340 include dry etching processes. In some other embodiments, the one or more etching processes 340 include wet etching processes. As a result of the one or more etching processes 340, portions of the upper surfaces of the passivation layer 240 are exposed. The patterned photoresist layer 320 are then removed, for example, through a photoresist ashing process or a photoresist stripping process.

At this stage of fabrication, the remaining portions of the conductive capping layer 300, the conductive pad layer 280, and the diffusion barrier layer 270 have a dimension 350 measured in the X-direction. This dimension 350 may be configured to be wide enough to cover the interconnect element 220. In other words, the dimension 350 may be longer than a width of the interconnect element 220 in the X-direction. In some embodiments, the dimension 350 is in a range between about 60 microns and about 80 microns.

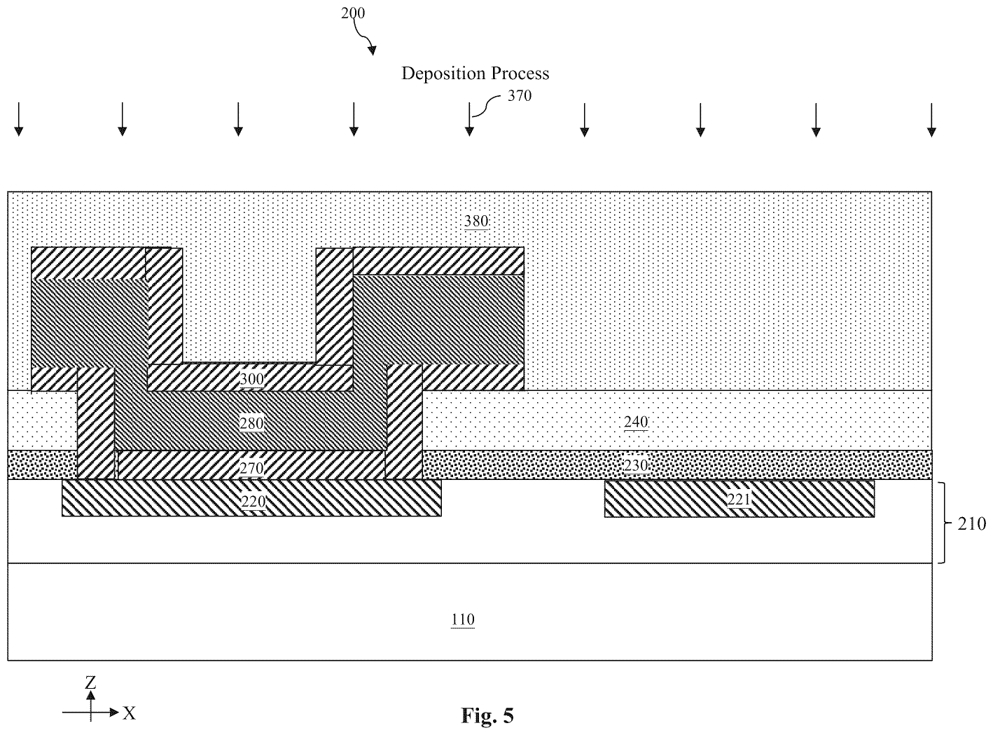

Referring now to FIG. 5, a deposition process 370 is performed to the IC device 200 to form a dielectric layer 380 over the conductive capping layer 300 and over the exposed surfaces of the passivation layer 240. In some embodiments, the deposition process 370 may include a CVD process, a PVD process, or an ALD process. In some embodiments, the dielectric layer 380 includes a silicon oxide (SiO₂) material. In some other embodiments, the dielectric layer 380 includes a silicon oxycarbide (SiOC) material.

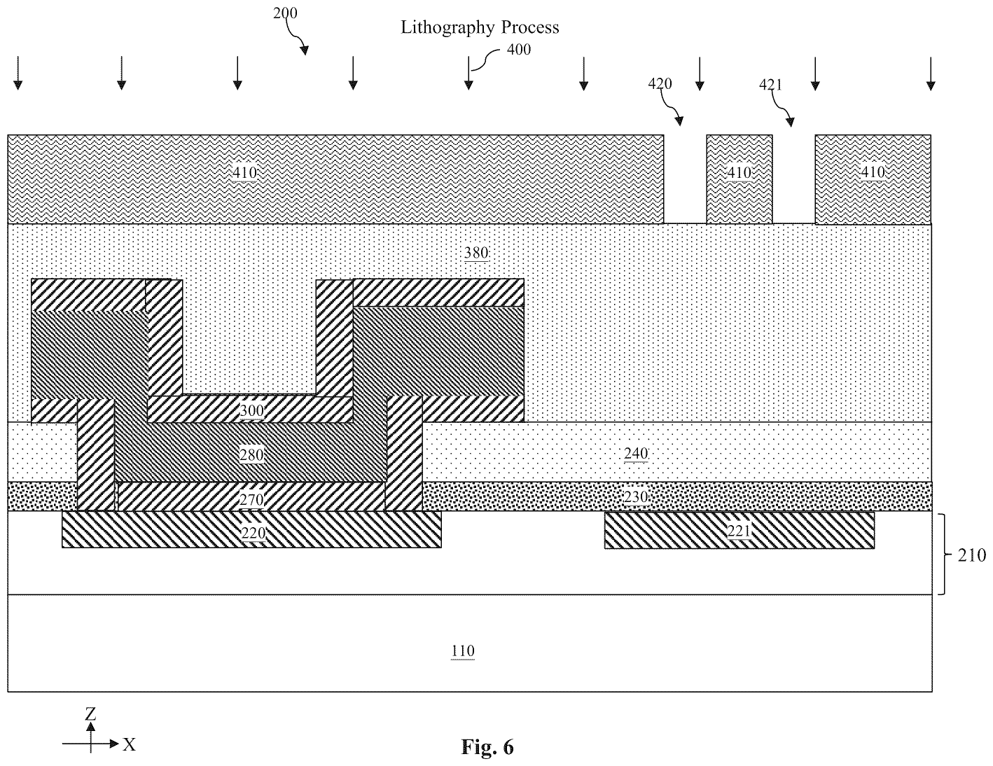

Referring now to FIG. 6, a lithography process 400 is performed to the IC device 200. The lithography process 400 form a photoresist film 410 over the dielectric layer 380, for example, through a photoresist spin coating process. The lithography process 400 then performs one or more processes such as pre-exposure baking, exposing, post-exposure baking, and developing processes, to form openings 420 and 421 in the photoresist film 410. The openings 420 and 421 are formed over the portion of the dielectric layer 380 overlying the interconnect element 221. These openings 420 and 421 will be used later to define the locations of conductive vias for the interconnect element 221.

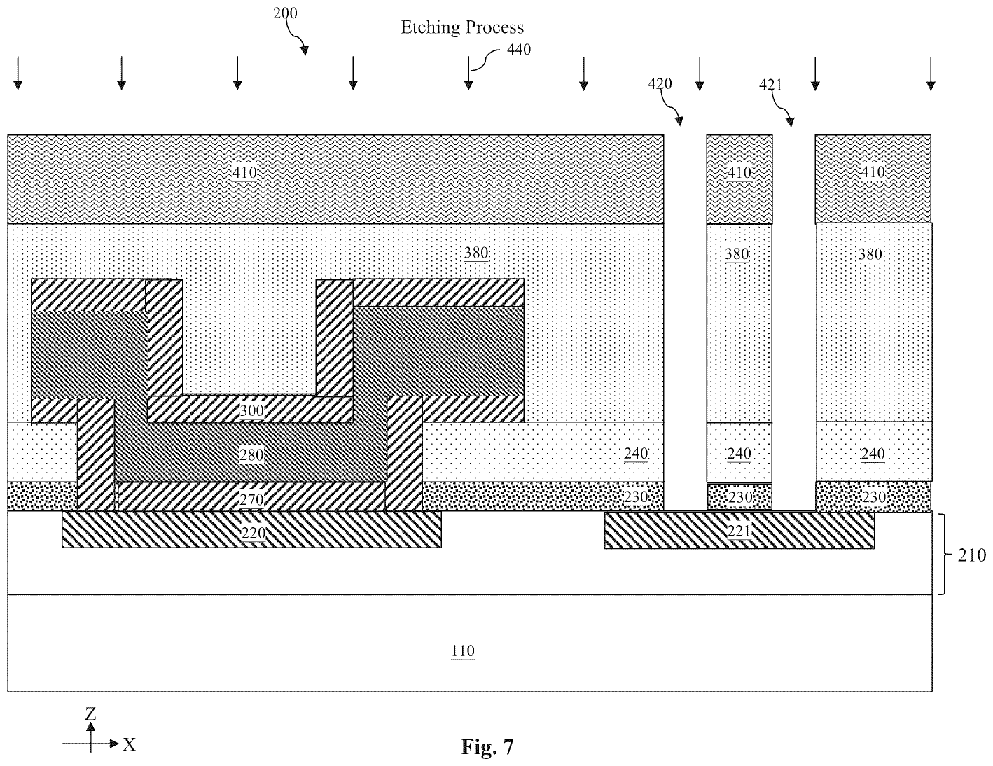

Referring now to FIG. 7, an etching process 440 is performed to the IC device 200 to extend the openings 420 and 421 vertically downwards through the dielectric layer 380, the passivation layer 240, and the etch stop layer 230. The openings 420 and 421 expose portions of an upper surface of the interconnect element 221. The openings 420 and 421 will be filled later by a conductive material to form conductive vias therein. As such, the openings 420 and 421 may also be interchangeably referred to as via holes 420 and 421.

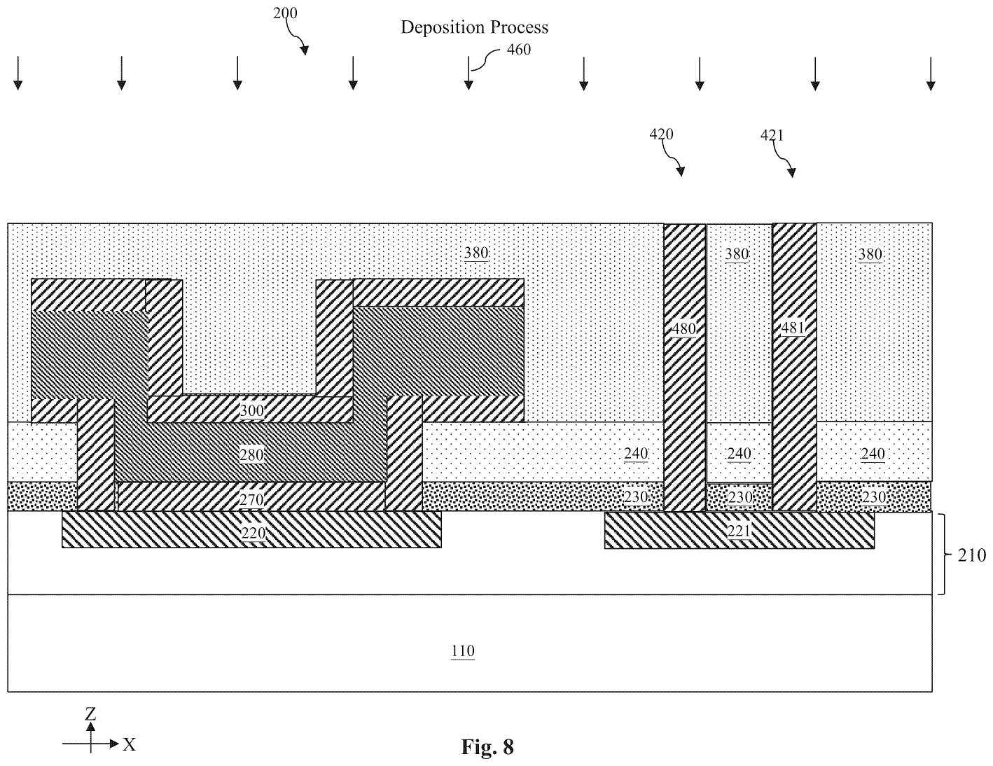

Referring now to FIG. 8, the photoresist film 410 is removed, for example, through a photoresist stripping or ashing process. Thereafter, a deposition process 460 is performed to the IC device 200 to deposit a conductive material in the via holes 420 and 421. In some embodiments, the deposition process 460 includes an ALD process, a CVD process, or a PVD process. In some embodiments, the conductive material deposited into the via holes 420 and 421 may include tungsten. In other embodiments, the conductive material deposited into the via holes 420 and 421 may include copper. It is understood that a planarization process (e.g., a chemical mechanical polishing (CMP) process) may be performed to the conductive material to planarize the upper surfaces of the deposited conductive material until they are substantially co-planar with the upper surfaces of the dielectric layer 380. At this stage of fabrication, conductive vias 480 and 481 are formed by the conductive materials filling the via holes 420 and 421.

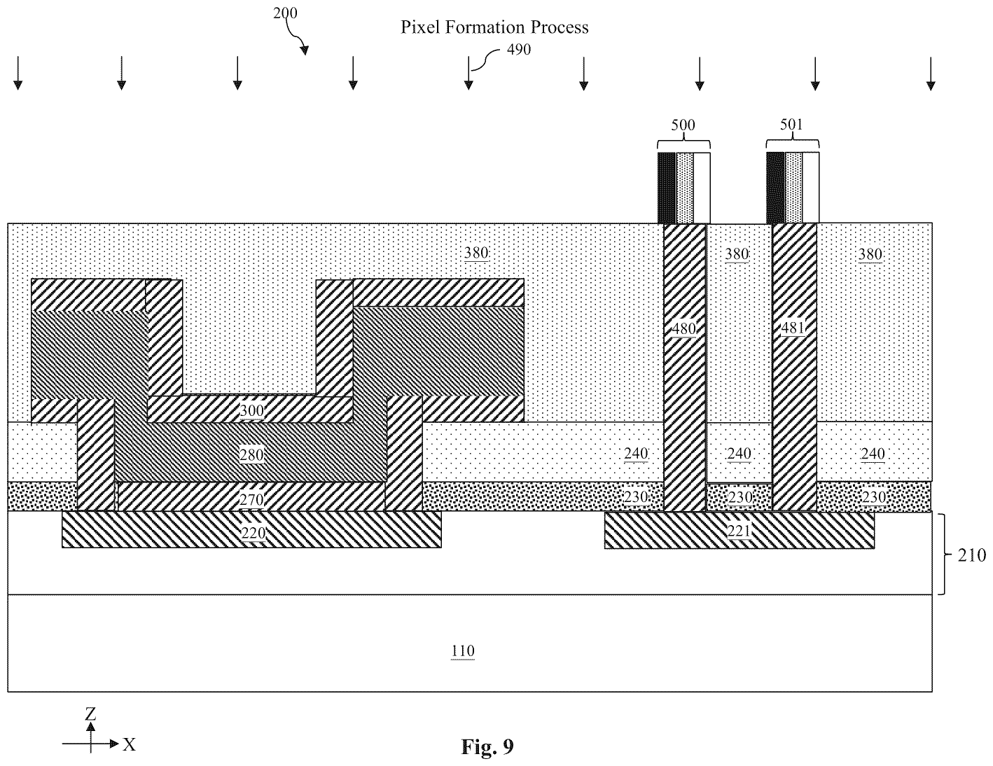

Referring now to FIG. 9, a pixel formation process 490 is performed to the IC device 200 to form a pixel 500 and a pixel 501. The pixel 500 is formed directly on the upper surface of the conductive via 480, and the pixel 501 is formed directly on the upper surface of the conductive via 481. In some embodiments, the pixels 500 and 501 are pixels of a light emitting diode (LED) device, for example, an organic light emitting diode (OLED) device, an ultra light emitting diode (ULED) device, or a quantum dots light emitting diode (QLED) device. In that regard, LED devices have been used in electronic applications such as display screens of mobile phones, computer monitors, television sets, etc. The display screen may include a plurality of pixels (such as the pixels 500 and 501) that can be individually addressed. The pixels 500 and 501 may include organic compounds that emit light in response to an electrical current.

The colors of the pixels 500 and 501 can also be configured. In some embodiments, each of the pixels 500 and 501 includes a red component, a green component, and a blue component. In these embodiments, the pixels 500 and 501 may be referred to as RGB pixels. In some other embodiments, each of the pixels 500 and 501 includes a red component, a green component, a blue component, and another green component. In these embodiments, the pixels 500 and 501 may be referred to as RGBG pixels. Regardless of the specific implementation of the pixels 500 and 501, it is understood that they may be electrically coupled to first circuitry within the substrate 110 through the conductive vias 480-481 and the interconnect element 221. In other words, the pixels 500 and 501 may be operated by controlling the corresponding first circuitry that resides within (or over) the substrate 110, where the electrical connections between such first circuitry and the pixels 500 and 501 are established at least in part through the interconnect element 221 and the conductive vias 480 and 481.

For the pixels 500-501 to be formed (and later operated) in an intended manner, accurate alignment may be needed during its formation process (e.g., the pixel formation process 490). For example, it is desirable to accurately align the pixels 500-501 with their respective vias 480-481. As discussed above (and will be discussed in more detail below), the material compositions, configurations, and thickness ranges of the conductive pad layer 280 and the conductive capping layer 300 of the present disclosure are specifically configured to reduce reflectivity, which allows more accurate alignment to be achieved with respect to the formation (and the intended operation) of the pixels 500-501. Therefore, device performance and/or yield may be improved.

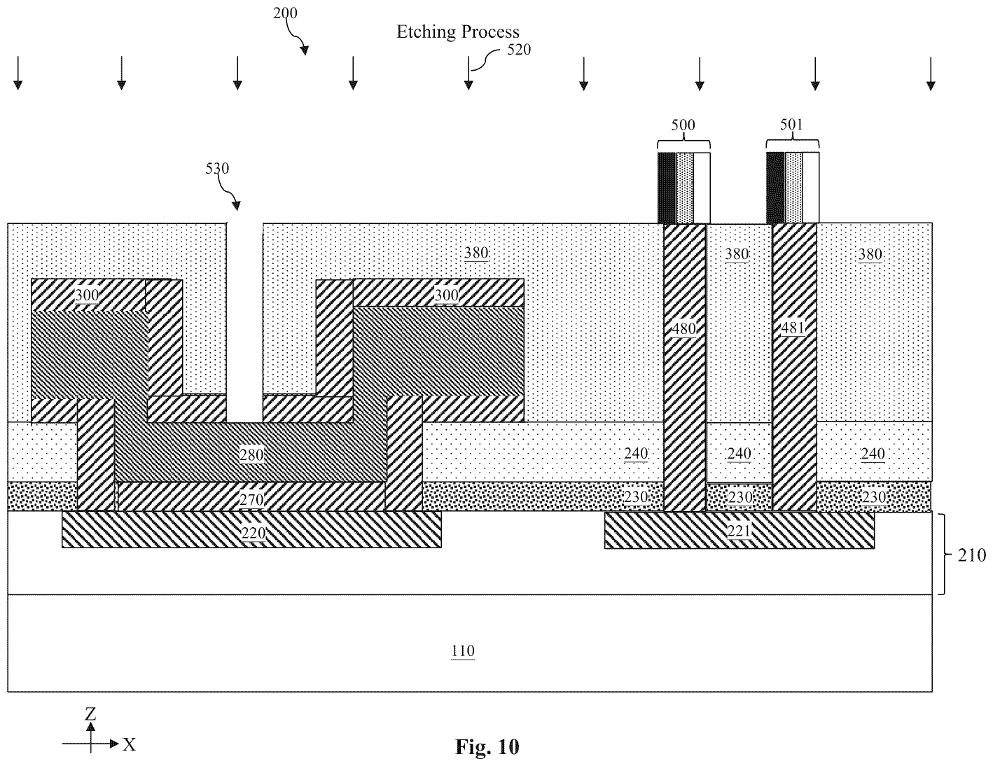

Referring now to FIG. 10, an etching process 520 is performed to the IC device 200 to form a contact hole 530. In some embodiments, the etching process 520 includes a dry etching process in some embodiments or a wet etching process in other embodiments. The contact hole 30 extends vertically through the dielectric layer 380 and the conductive capping layer 300. The contact hole 530 exposes a portion of an upper surface of the conductive pad layer 280.

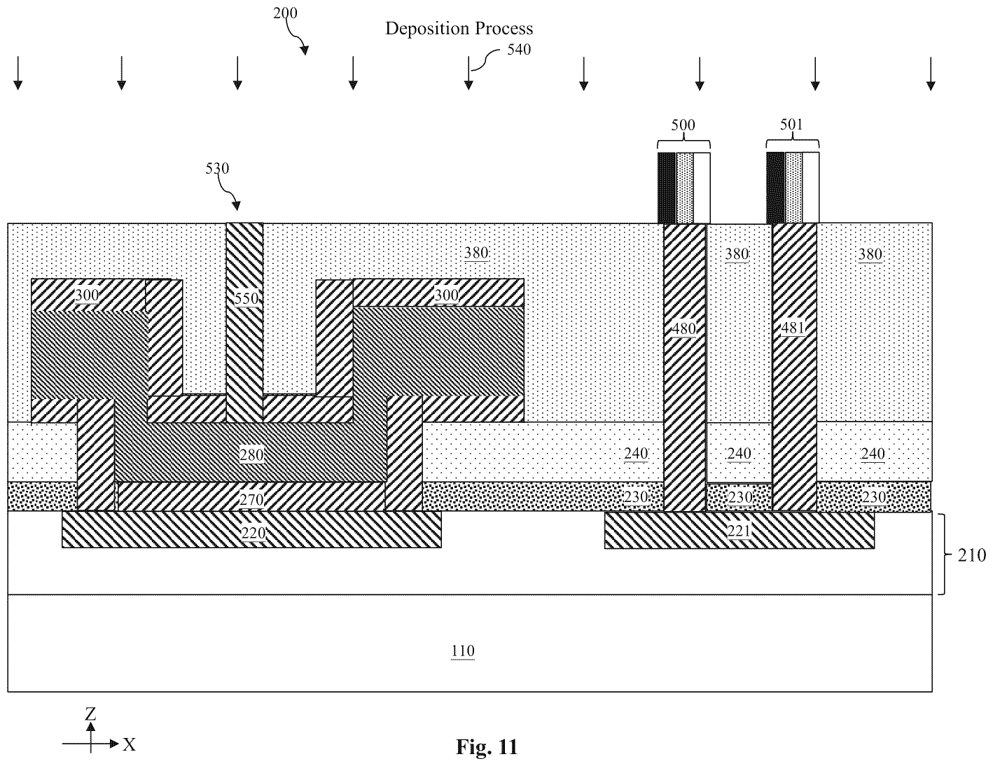

Referring now to FIG. 11, a deposition process 540 is performed to the IC device 200 to fill the contact hole 530 with a conductive material. In some embodiments, the deposition process 540 may include a CVD process, a PVD process, or an ALD process. In some embodiments, the conductive material deposited into the contact hole 530 includes tungsten. In some other embodiments, the conductive material deposited into the contact hole 530 includes copper. A planarization process may be performed to planarize the upper surface of the conductive material until it is substantially co-planar with the upper surface of the dielectric layer 380. At this stage of fabrication, a conductive contact 550 is formed by the conductive material filling the contact hole 530. It is understood that the conductive contact is electrically coupled to second circuitry within the substrate 110 through the conductive pad layer 280, the diffusion barrier layer 270, and the interconnect element 220. As such, electrical access to the second circuitry may be gained at least in part through the conductive contact 550.

As is the case for the pixels 500-501, accurate alignment may be needed during the formation of the conductive contact 550. As discussed above (and will be discussed in more detail below), the material compositions, configurations, and thickness ranges of the conductive pad layer 280 and the conductive capping layer 300 of the present disclosure are specifically configured to reduce reflectivity, which allows more accurate alignment to be achieved with respect to the formation of the conductive contact 550. Therefore, device performance and/or yield may be improved.

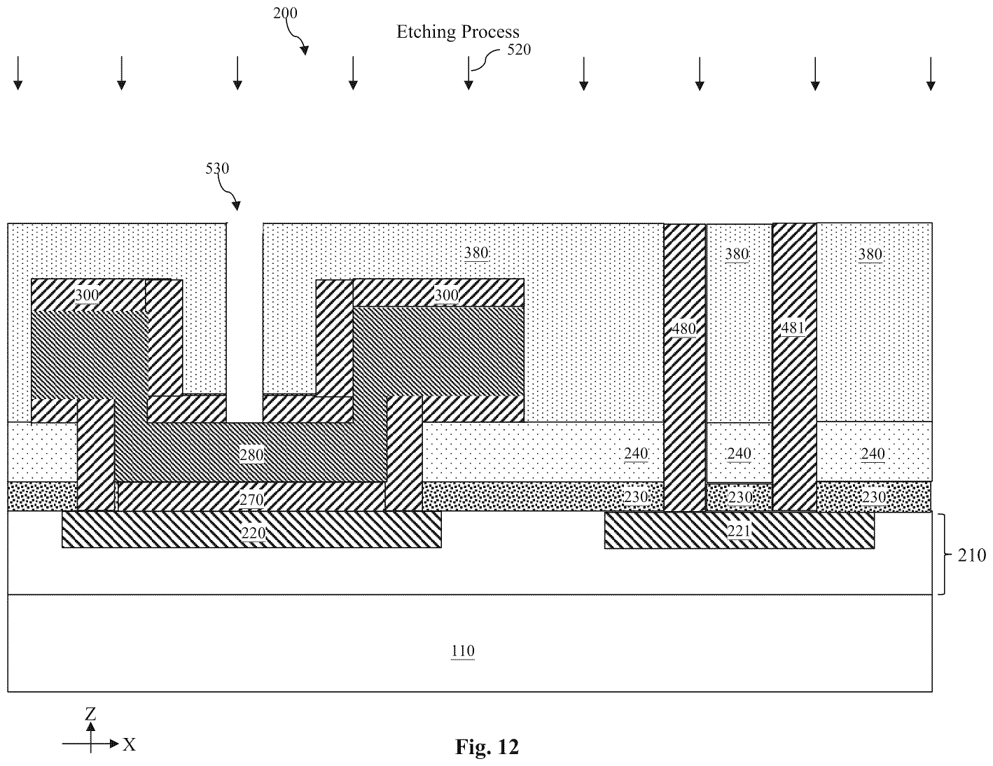

FIGS. 12-14 illustrate diagrammatic fragmentary cross-sectional side views of the IC device 200 according to an alternative embodiment of the present disclosure. For reasons of consistency and clarity, similar components in FIGS. 2-11 and FIGS. 12-14 will be labeled the same. One difference between the embodiment shown in FIGS. 12-14 and the embodiment shown in FIGS. 2-11 is that, in the embodiment of FIGS. 12-14, the pixels 500 and 501 are formed after the formation of the conductive contact 550. For example, at the stage of fabrication shown in FIG. 12, the conductive vias 480 and 481 are already formed. However, rather than forming the pixels 500 and 501 directly above the conductive vias 480 and 481, the etching process 520 is performed instead to the IC device 200 to etch a contact hole 530 that extends vertically through the dielectric layer 380 and the conductive capping layer 300. The contact hole 530 exposes a portion of an upper surface of the conductive pad layer 280.

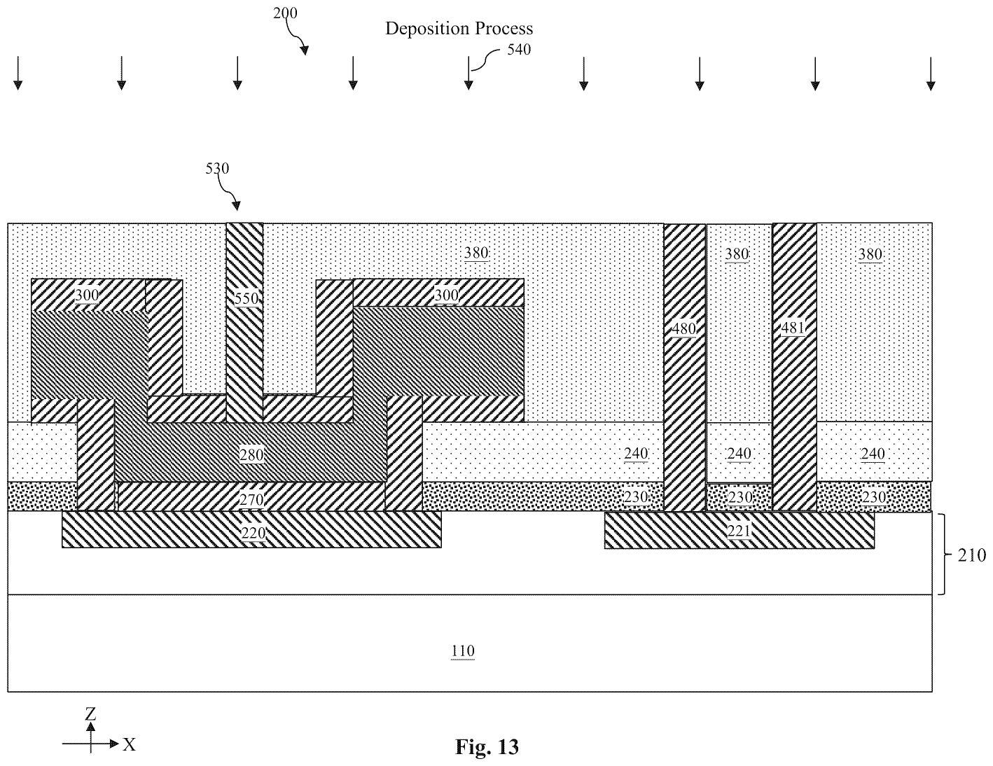

Referring now to FIG. 13, the deposition process 540 is performed to the IC device 200 to deposit a conductive material, such as tungsten or copper, into the contact hole 530. A planarization process may be performed to planarize the upper surface of the conductive material until it is substantially co-planar with the upper surface of the dielectric layer 380. As a result, the conductive contact 550 is formed in the contact hole 530.

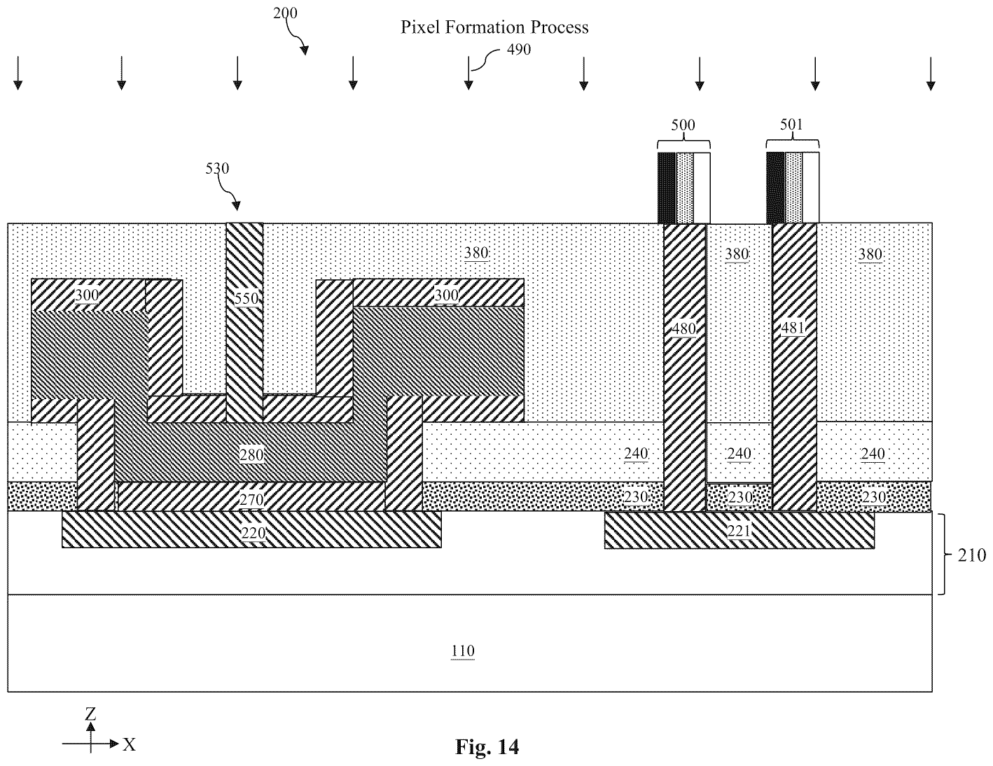

Referring now to FIG. 14, the pixel formation process 490 is performed to the IC device 200 to form the pixels 500 and 501 over the upper surfaces of the conductive vias 480 and 481, respectively. As discussed above, the pixels 500 and 501 may be pixels of an LED device, such as an OLED device. The pixels 500 and 501 are electrically coupled to the first circuitry inside the substrate 110 at least in part through the conductive vias 480-481 and the interconnect element 221, as well as other interconnect layers of the interconnect structure 210.

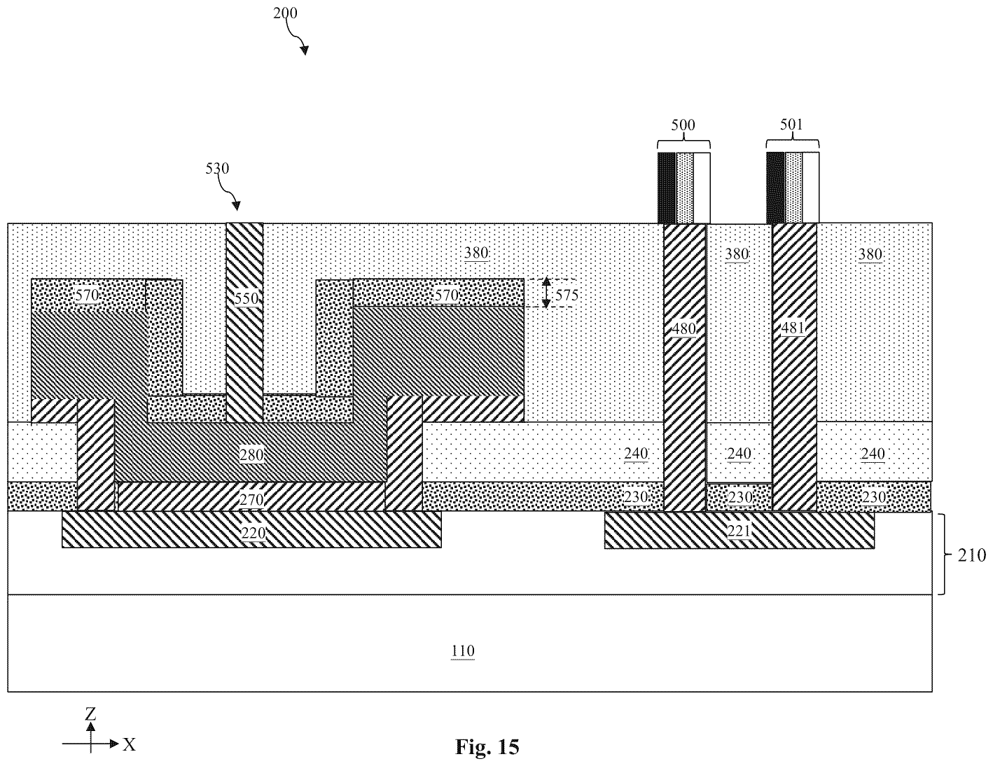

FIG. 15 illustrates a diagrammatic fragmentary cross-sectional side view of the IC device 200 according to yet another alternative embodiment of the present disclosure. For reasons of consistency and clarity, similar components in FIGS. 2-11 and FIG. 15 are labeled the same. One difference between the embodiment shown in FIG. 15 and the embodiment shown in FIGS. 2-11 is that no conductive capping layer 300 is formed in the embodiment of FIG. 15. Instead, one of the deposition processes 260 discussed above (with reference to FIG. 3) forms a dielectric capping layer 570 over the conductive pad layer 280. In some embodiments, the dielectric capping layer 570 includes silicon oxynitride (SiON). The dielectric capping layer 570 is also formed to have a thickness 575 that is measured in the Z-direction. In some embodiments, the thickness 575 is in a range between about 200 angstroms and about 1000 angstroms. Such a thickness range is specifically configured to lower the reflectivity and reduce the likelihood of defects such as hillocks.

Note that in the embodiment of FIG. 15, the conductive pad layer 280 has a material composition that is either aluminum that is doped with silicon, or aluminum that is doped with ruthenium. These candidate materials of the conductive pad layer 280 are more thermally stable than conventional conductive pad materials, which helps improve the hillock issue (e.g., reduces the bumps on or in the conductive pad layer 280 or the dielectric capping layer 570). These candidate materials of the conductive pad layer 280 also have lower reflectivity than conventional conductive pad materials, which also improves the alignment during the fabrication of the IC device 200, for example, during the formation of the pixels 500-501.

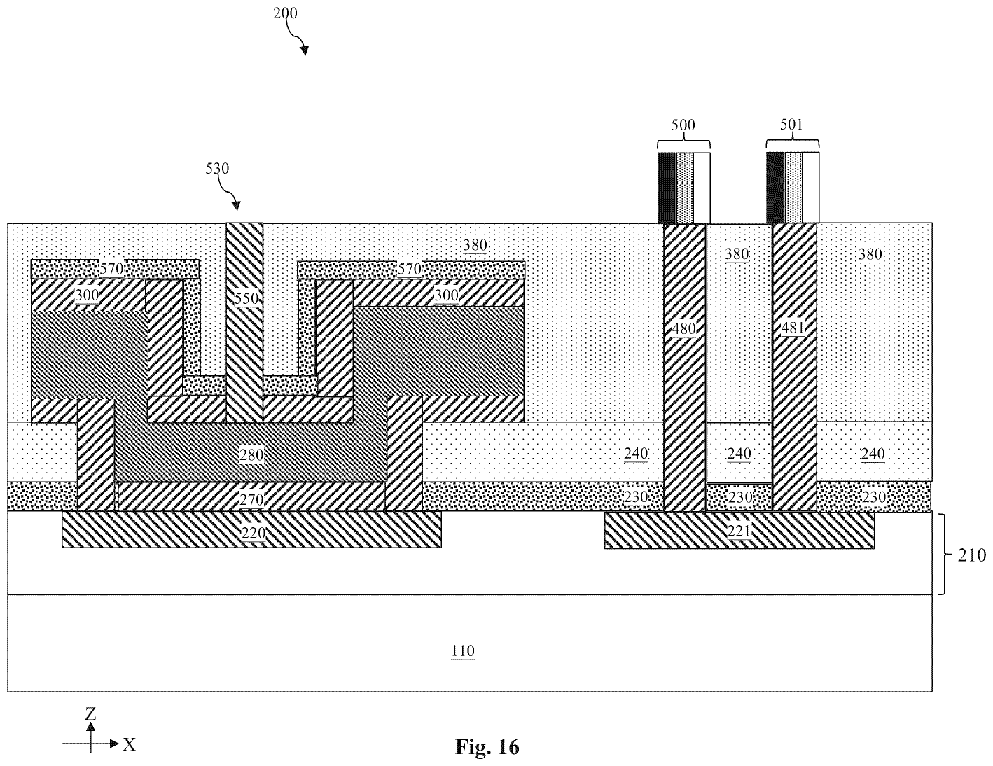

FIG. 16 illustrates a diagrammatic fragmentary cross-sectional side view of the IC device 200 according to a further embodiment of the present disclosure. For reasons of consistency and clarity, similar components in FIGS. 2-11 and FIG. 16 are labeled the same. One difference between the embodiment shown in FIG. 16 and the embodiment shown in FIGS. 2-11 is that the IC device 200 of FIG. 16 has multiple capping layers. For example, the conductive capping layer 300 is formed directly on the conductive pad layer 280, and the dielectric capping layer 570 is formed directly on the conductive capping layer 300. The dielectric layer 380 is then formed directly on the dielectric capping layer 570.

The conductive capping layer 300 and the dielectric capping layer 570 have different material compositions. In some embodiments, the conductive capping layer 300 has a titanium nitride material composition, while the dielectric layer 570 has a silicon oxynitride material composition. Regardless of the material compositions of the conductive capping layer 300 and/or the dielectric capping layer 570, it is understood that the conductive pad layer 280 may still have a material composition that includes aluminum doped with another material. In some embodiments, the conductive pad layer 280 includes aluminum that is doped with copper. In some other embodiments, the conductive pad layer 280 includes aluminum that is doped with silicon. In yet other embodiments, the conductive pad layer 280 includes aluminum that is doped with ruthenium.

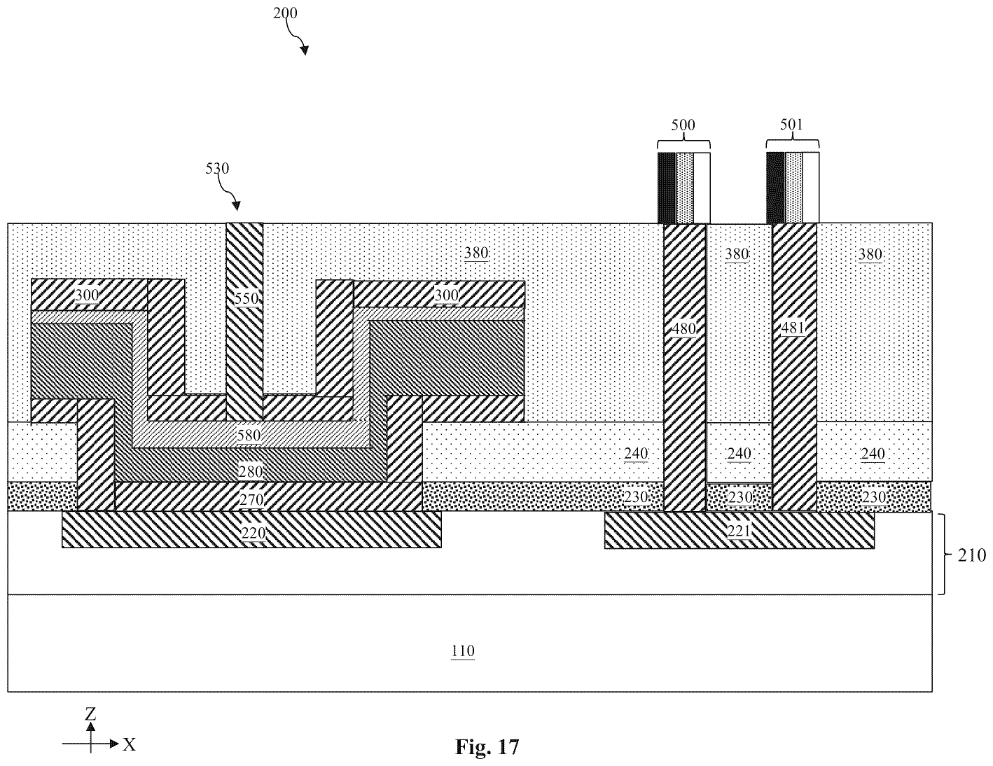

FIG. 17 illustrates a diagrammatic fragmentary cross-sectional side view of the IC device 200 according to another embodiment of the present disclosure. For reasons of consistency and clarity, similar components in FIGS. 2-11 and FIG. 17 are labeled the same. One difference between the embodiment shown in FIG. 17 and the embodiment shown in FIGS. 2-11 is that the IC device 200 of FIG. 17 includes multiple conductive pad layers 280 and 580. In more detail, the conductive pad layer 280 is formed directly on the diffusion barrier layer 270, and another conductive pad layer 580 is formed directly on the conductive pad layer 280. The conductive capping layer 300 is formed directly on the conductive pad layer 580.

The conductive pad layer 280 and the conductive pad layer 580 have different material compositions. In some embodiments, the conductive pad layer 280 includes aluminum that is doped with copper, while the conductive pad layer 280 includes aluminum that is doped with silicon. In some other embodiments, the conductive pad layer 280 includes aluminum that is doped with copper, while the conductive pad layer 280 includes aluminum that is doped with ruthenium. In yet other embodiments, the conductive pad layer 280 includes aluminum that is doped with silicon, while the conductive pad layer 280 includes aluminum that is doped with copper. In further embodiments, the conductive pad layer 280 includes aluminum that is doped with ruthenium, while the conductive pad layer 280 includes aluminum that is doped with copper.

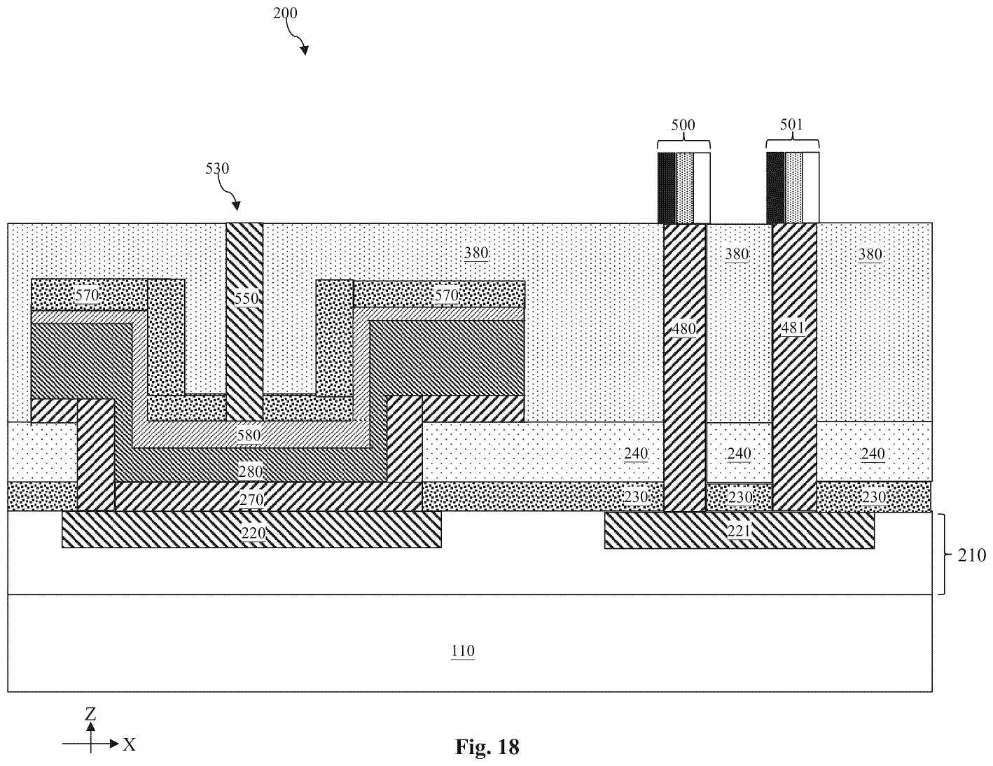

FIG. 18 illustrates a diagrammatic fragmentary cross-sectional side view of the IC device 200 according to yet another embodiment of the present disclosure. For reasons of consistency and clarity, similar components in FIGS. 2-17 and FIG. 18 are labeled the same. Similar to the embodiment of FIG. 17, the embodiment of FIG. 18 also includes multiple conductive pad layers, such as the conductive pad layers 280 and 580. However, unlike the embodiment of FIG. 17, the embodiment of FIG. 18 includes the dielectric capping layer 570, rather than the conductive capping layer 300. The dielectric capping layer 570 is formed directly on the conductive pad layer 580. In some embodiments, the conductive pad layer 580 includes aluminum that is doped with either silicon or ruthenium, and the conductive pad layer 280 includes aluminum that is doped with copper. Such a configuration may be desirable, since it prevents the dielectric capping layer 570 from coming into direct contact with the aluminum that is doped with copper, as that could have led to formation of defects such as hillocks.

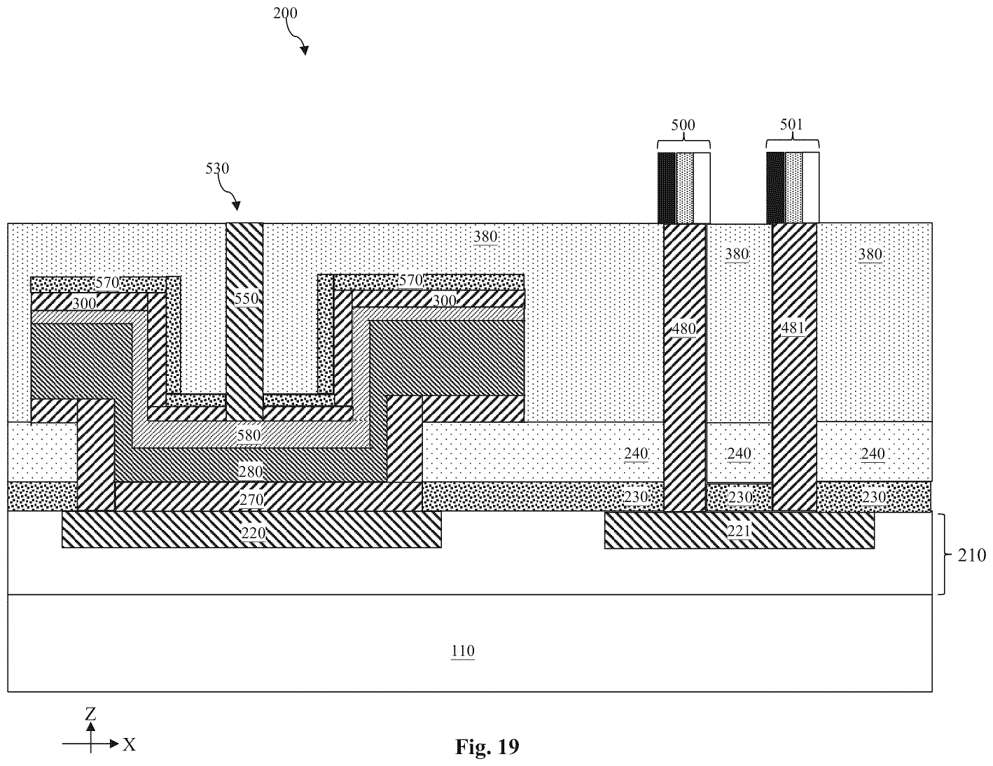

FIG. 19 illustrates a diagrammatic fragmentary cross-sectional side view of the IC device 200 according to a further embodiment of the present disclosure. For reasons of consistency and clarity, similar components in FIGS. 2-18 and FIG. 19 are labeled the same. Similar to the embodiments of FIG. 17-18, the embodiment of FIG. 18 also includes multiple conductive pad layers, such as the conductive pad layers 280 and 580. However, unlike the embodiments of FIG. 17-18, the IC device 200 of the embodiment of FIG. 19 also includes multiple capping layers. For example, the IC device 200 includes the conductive capping layer 300 that is formed directly on the conductive pad layer 580, as well as the dielectric capping layer 570 that is formed directly on the conductive capping layer 300. In some embodiments, the conductive capping layer 300 includes titanium nitride, while the dielectric capping layer 570 includes silicon oxynitride.

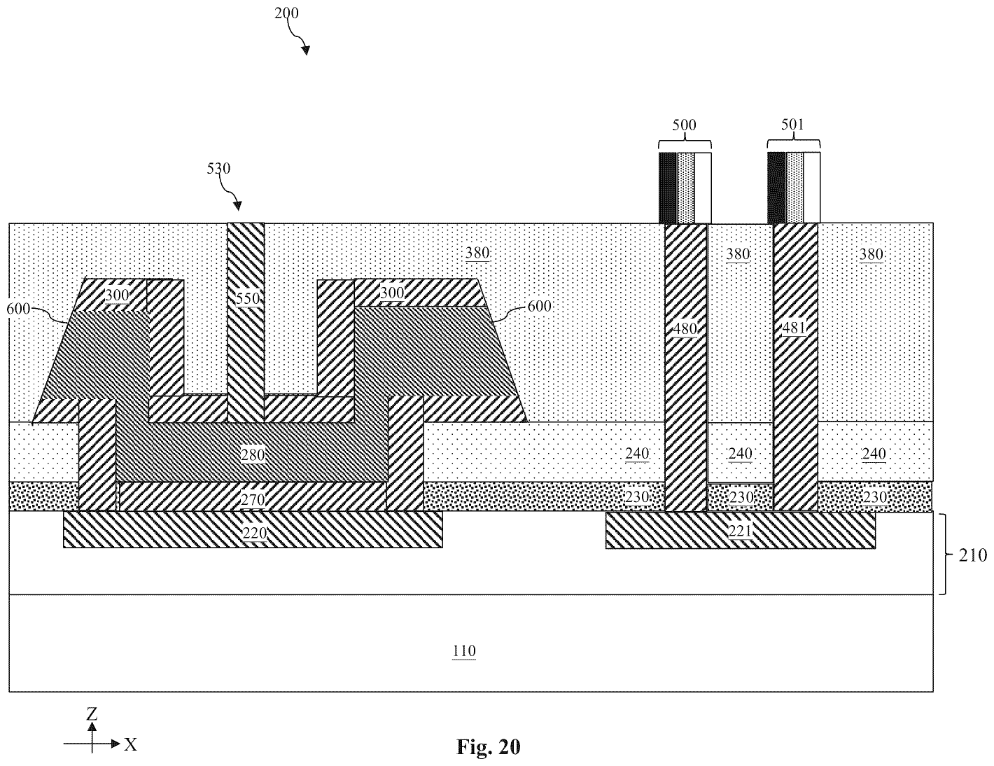

FIG. 20 illustrates a diagrammatic fragmentary cross-sectional side view of the IC device 200 according to another embodiment of the present disclosure. For reasons of consistency and clarity, similar components in FIGS. 2-19 and FIG. 20 are labeled the same. Similar to the embodiment of FIG. 14, the embodiment of FIG. 20 includes the conductive pad layer 280 and the conductive capping layer 300 formed over the conductive pad layer 280. However, whereas the side surfaces of the conductive pad layer 280 and the side surfaces of the conductive capping layer 300 in the embodiment of FIG. 14 are substantially straight in the vertical Z-direction, the side surfaces of the conductive pad layer 280 and the side surfaces of the conductive capping layer 300 in the embodiment of FIG. 20 are substantially tapered. For example, the conductive pad layer 280 and the conductive capping layer 300 have side surfaces 600 that are slanted in the X-direction, such that the conductive pad layer 280 and the conductive capping layer 300 each have narrower upper surfaces and wider bottom surfaces. One benefit of having the slanted side surfaces 600 herein is that it may be easier to tune the etching parameters of the etching process 340 (see FIG. 4). It is understood that the tapered profile of FIG. 20 is not limited to just the embodiment where there is a single conductive pad layer 280 and a single conductive capping layer 300. In embodiments where there are multiple conductive pad layers and/or multiple conductive capping layers, these multiple conductive pad layers and/or multiple conductive capping layers may also have slanted side surfaces.

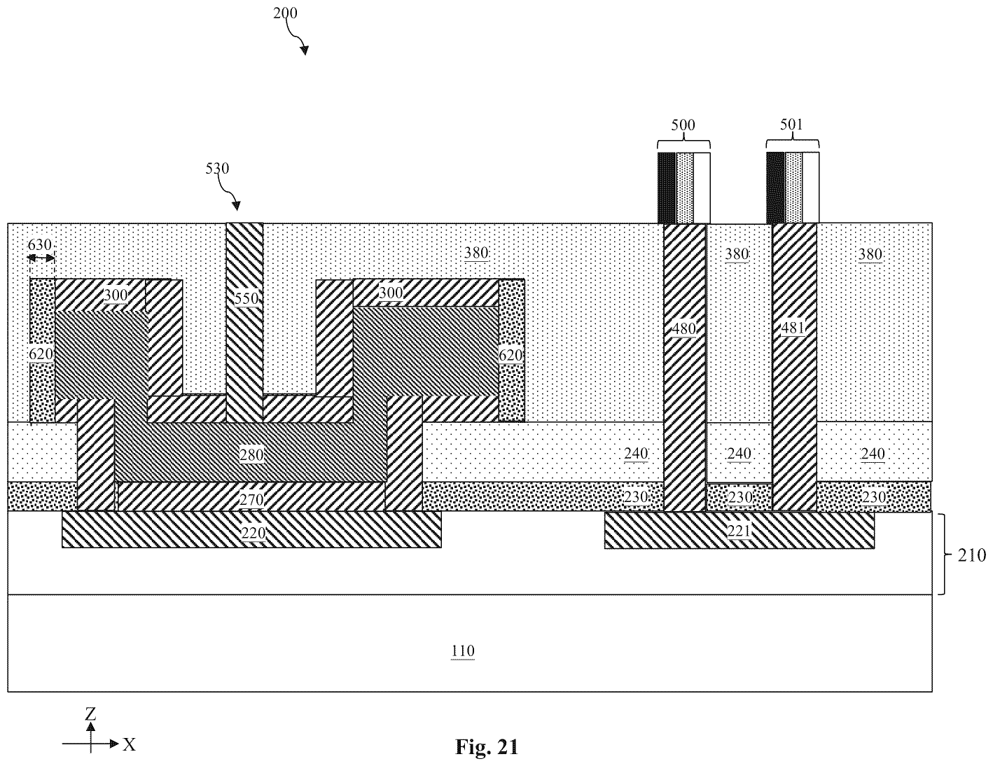

FIG. 21 illustrates a diagrammatic fragmentary cross-sectional side view of the IC device 200 according to yet another embodiment of the present disclosure. For reasons of consistency and clarity, similar components in FIGS. 2-10 and FIG. 21 are labeled the same. For example, similar to the embodiment of FIG. 14, the embodiment of FIG. 21 includes the conductive pad layer 280 and the conductive capping layer 300 formed over the conductive pad layer 280. However, whereas the side surfaces of the diffusion barrier layer 270, the conductive pad layer 280, and the conductive capping layer 300 are surrounded by the dielectric layer 380 in the embodiment of FIG. 14, the side surfaces of the diffusion barrier layer 270, the conductive pad layer 280, and the conductive capping layer 300 are surrounded by a sidewall capping layer 620 in the embodiment of FIG. 21.

The sidewall capping layer 620 may be formed by performing a deposition process to deposit a dielectric film over the upper surface of the passivation layer 240, over the side surfaces of the diffusion barrier layer 270, the conductive pad layer 280, and the conductive capping layer 300, and over the upper surface of the conductive capping layer 300. In some embodiments, the deposition process may include a CVD process, a PVD process, or an ALD process. In some embodiments, the deposited dielectric film may include silicon nitride, silicon oxynitride, or silicon oxycarbide. One or more etching processes, such as wet etching processes or dry etching processes, may then be performed to the deposited dielectric film. The etching processes removes portions of the dielectric film until the sidewall capping layer 620 is formed by the remaining portions of the dielectric film on the side surfaces of the diffusion barrier layer 270, the conductive pad layer 280, and the conductive capping layer 300.

One benefit of the sidewall capping layer 620 is that it prevents the side surfaces of the diffusion barrier layer 270, the conductive pad layer 280, and the conductive capping layer 300 from being oxidized. Oxidation of these layers 270, 280, and/or 300 would have been undesirable, because that would have led to an increase in parasitic resistance, which in turn may slow down device speed or increase power consumption, etc. Since the side surfaces of the layers 270, 280, and 300 are protected by the sidewall capping layer 620, they are less likely to become oxidized during the fabrication of the IC device 200, which in turn reduces parasitic resistance and improves device performance.

The sidewall capping layer has a thickness 630. In some embodiments, the thickness 630 is in a range between about 10 angstroms and about 800 angstroms. Such a range of the thickness 630 can adequately protect the layers 270, 280, and 300 from being undesirably oxidized, while minimizing interference with other device components. It is understood that s similar sidewall capping layer may be formed in embodiments where the IC device 200 has multiple conductive pad layers and/or multiple capping layers as well, in order to prevent these multiple conductive pad layers and/or multiple capping layers from becoming oxidized.

FIG. 22 illustrates an integrated circuit fabrication system 900 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such the processing tools to perform the various deposition processes discussed above; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 23 is a flowchart illustrating a method 1000 of fabricating a semiconductor device. The method 1000 includes a step 1010 to form a conductive pad layer over an interconnect structure that includes a first interconnect element and a second interconnect element. The conductive pad layer has a first material composition.

The method 1000 includes a step 1020 to form a capping layer over the conductive pad layer. The capping layer has a second material composition.

The method 1000 includes a step 1030 to perform a patterning process. The patterning process removes portions of the conductive pad layer and the capping layer over the second interconnect element.

The method 1000 includes a step 1040 to form a dielectric layer over the capping layer.

The method 1000 includes a step 1050 to etch a contact hole and a via hole through the dielectric layer. The contact hole partially exposes the first interconnect element. The via hole partially exposes the second interconnect element.

In some embodiments, the contact hole is filled with a conductive contact, and the via hole is filled with a conductive via. In some embodiments, the first material composition include aluminum that is doped with copper, and the second material composition includes titanium nitride. In some other embodiments, the first material composition include aluminum that is doped with silicon or ruthenium, and the second material composition includes silicon oxynitride. In yet other embodiments, the first material composition include aluminum that is doped with silicon or ruthenium, and the second material composition includes titanium nitride.

In some embodiments, the capping layer is formed through a deposition process that is performed at a room temperature (e.g., between about 20 degrees Celsius and about 30 degrees Celsius).

In some embodiments, the conductive pad layer is a first conductive pad layer. In some embodiments, the method 1000 further comprises forming a second conductive pad layer over the first conductive pad layer. The capping layer is formed over the second conductive pad layer. One of the first conductive pad layer and the second conductive pad layer includes aluminum doped with copper. Another one of the first conductive pad layer and the second conductive pad layer includes aluminum doped with silicon or ruthenium.

It is understood that additional steps may be performed before, during, or after the steps 1010-1060. For example, in some embodiments, the method 1000 may further include a step of forming a pixel over the conductive via. As another example, the method 1000 may further include a step of forming a sidewall capping layer on a side surface of the conductive pad layer and on a side surface of the capping layer, which may be performed after the patterning process is performed but before the dielectric layer is formed. For reasons of simplicity, these additional processes are not discussed herein in detail.

Based on the above discussions, it can be seen that the present disclosure implements a unique scheme where a conductive pad layer and a capping layer are implemented. The material composition of the conductive pad layer may include aluminum that is doped with copper, aluminum that is doped with silicon, or aluminum that is doped with ruthenium. The material composition of the capping layer may include a conductive material in some embodiments, such as titanium nitride. The material composition of the capping layer may include a dielectric material in other embodiments, such as silicon oxynitride.

The unique fabrication process flow and the resulting IC device structure of the present disclosure offers advantages over conventional devices. It is understood, however, that no particular advantage is required, other embodiments may offer different advantages, and that not all advantages are necessarily disclosed herein. One advantage is the reduction in device defects. For example, when the conductive pad layer is implemented using aluminum that is doped with silicon or aluminum that is doped with ruthenium, the resulting conductive pad layer has greater thermal stability than conventional conductive pad layers. The greater thermal stability leads to a reduction in device defects such as hillocks (e.g., bumps or excessive topography variations) and an improvement in yield. In addition, in embodiments where the capping layer includes the conductive material such as titanium nitride or oxygen-doped titanium nitride, such a capping layer may be deposited at a lower deposition temperature, which is not the case in conventional capping layers. The lower deposition temperature also leads to a reduction in the device defects and improvement in yield. Another advantage is an improvement in alignment accuracy. For example, when the conductive pad layer is implemented using aluminum that is doped with silicon or aluminum that is doped with ruthenium, it has a lower reflectivity than conventional conductive pad layers. The lower reflectivity allows accurate alignment to be achieved between layers during fabrication processes. Other advantages may include ease of fabrication and compatibility with existing fabrication processes.

The advanced lithography process, method, and materials described above can be used in many applications, including in IC devices using fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

One aspect of the present disclosure pertains to a device. The device includes an interconnect structure that includes at least a first interconnect element and a second interconnect element. A conductive pad layer is disposed over, and electrically coupled to, the first interconnect element. A capping layer is disposed over the conductive pad layer. The capping layer includes titanium nitride. A dielectric layer is disposed over the capping layer. A conductive contact extends vertically through at least a first portion of the dielectric layer and the capping layer. The conductive contact is coupled to the first interconnect element through the conductive pad layer. A conductive via extends vertically through at least a second portion of the dielectric layer. The conductive via is coupled to the second interconnect element.

Another aspect of the present disclosure pertains to a device. The device includes an interconnect structure that includes at least a first interconnect element and a second interconnect element. An etch stop layer is formed over the interconnect structure. A passivation layer is formed over the etch stop layer. The device also includes diffusion barrier layer. A first segment of the diffusion barrier layer at least partially extends through the etch stop layer and is electrically coupled to the first interconnect element. A second segment of the diffusion barrier layer is formed over the passivation layer. A conductive pad layer is formed over the diffusion barrier layer. The conductive pad layer includes aluminum that is doped with silicon or aluminum that is doped with ruthenium. A capping layer is formed over the conductive pad layer. A dielectric layer is formed over the capping layer. A conductive contact extends vertically through at least a first portion of the dielectric layer and the capping layer. The conductive contact is electrically coupled to the conductive pad layer. A conductive via extends vertically through at least a second portion of the dielectric layer, the passivation layer, and the etch stop layer. The conductive via is electrically coupled to the second interconnect element. A pixel is formed over, and electrically coupled to, the conductive via.

Yet another aspect of the present disclosure pertains to a method. A conductive pad layer is formed over an interconnect structure that includes a first interconnect element and a second interconnect element. The conductive pad layer has a first material composition. A capping layer is formed over the conductive pad layer. The capping layer has a second material composition. A patterning process is performed. The patterning process removes portions of the conductive pad layer and the capping layer over the second interconnect element. A dielectric layer is formed over the capping layer. A contact hole and a via hole are etched through the dielectric layer. The contact hole partially exposes the first interconnect element, and the via hole partially exposes the second interconnect element. The contact hole is filled with a conductive contact, and the via hole is filled with a conductive via. The forming the conductive pad layer and the forming the capping layer are performed such that: the first material composition include aluminum that is doped with copper, and the second material composition includes titanium nitride; or the first material composition include aluminum that is doped with silicon or ruthenium, and the second material composition includes silicon oxynitride; or the first material composition include aluminum that is doped with silicon or ruthenium, and the second material composition includes titanium nitride.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
forming a conductive pad layer over a first interconnect element and a second interconnect element, the conductive pad layer containing a first type of material;
forming a capping layer over the conductive pad layer, the capping layer containing a second type of material different from the first type of material;
removing portions of the conductive pad layer and the capping layer disposed over the second interconnect element;
forming, after the removing, a dielectric layer over the capping layer;
etching a first opening and a second opening through the dielectric layer, wherein the first opening exposes at least a portion of the first interconnect element, and wherein the second opening exposes at least a portion of the second interconnect element; and
forming a first conductive component in the first opening and forming a second conductive component in the second opening.

2. The method of claim 1, wherein:
the forming the conductive pad layer comprises forming a conductive material that is doped as the conductive pad layer; and
the forming the capping layer comprises forming a material that contains nitrogen as the capping layer.

3. The method of claim 1, wherein:
the forming the conductive pad layer comprises forming aluminum that is doped with copper as the conductive pad layer; and
the forming the capping layer comprises forming titanium nitride as the capping layer.

4. The method of claim 1, wherein:
the forming the conductive pad layer comprises forming aluminum that is doped with silicon or ruthenium as the conductive pad layer; and
the forming the capping layer comprises forming silicon oxynitride as the capping layer.

5. The method of claim 1, wherein:
the forming the conductive pad layer comprises forming aluminum that is doped with silicon or ruthenium as the conductive pad layer; and
the forming the capping layer comprises forming titanium nitride as the capping layer.

6. The method of claim 1, wherein the forming the capping layer comprises performing a deposition process at a temperature between about 20 degrees Celsius and about 30 degrees Celsius.

7. The method of claim 1, further comprising forming a light-emitting diode (LED) over the second conductive component.

8. The method of claim 7, wherein:
the etching the second opening comprises etching a plurality of second openings;
the forming the second conductive component comprises forming a plurality of second conductive components in the plurality of second openings, respectively; and
the forming the LED comprises forming a plurality of LEDs over the plurality of second conductive components, respectively, wherein each of the LEDs is configured to emit a different color of light.

9. The method of claim 1, wherein the second opening is etched before the first opening is etched.

10. The method of claim 9, wherein the second conductive component is formed in the second opening before the first opening is etched.

11. The method of claim 1, further comprising forming an interconnect structure that includes the first interconnect element and the second interconnect element.

12. The method of claim 1, further comprising after the removing but before the forming the dielectric layer: forming a sidewall capping layer on a side surface of the conductive pad layer and on a side surface of the capping layer.

13. A method, comprising:
forming a conductive pad layer over a first interconnect element and a second interconnect element, wherein the conductive pad layer contains aluminum that is doped with one of: copper, silicon, or ruthenium;
forming a capping layer over the conductive pad layer, wherein the capping layer contains titanium nitride or silicon oxynitride;
removing portions of the conductive pad layer and the capping layer formed above the second interconnect element;
forming a dielectric layer over the capping layer;
etching a plurality of via holes that extend through the dielectric layer, the plurality of via holes exposing the second interconnect element;
filling the plurality of via holes with a plurality of conductive vias;
forming a plurality of pixels over the plurality of conductive vias, respectively;
etching a contact hole that extends through the dielectric layer, the contact hole exposing the first interconnect element; and
filling the contact hole with a conductive contact.

14. The method of claim 13, wherein the capping layer is formed through a deposition process with a temperature in a range between about 20 degrees Celsius and about 30 degrees Celsius.

15. The method of claim 13, further comprising: after the removing but before the forming the dielectric layer: forming a sidewall capping layer on a side surface of the conductive pad layer and on a side surface of the capping layer.

16. A method, comprising:
forming a conductive pad layer over an interconnect structure that includes a first interconnect element and a second interconnect element, wherein the conductive pad layer has a first material composition;
forming a capping layer over the conductive pad layer, wherein the capping layer has a second material composition;
performing a patterning process, the patterning process removing portions of the conductive pad layer and the capping layer over the second interconnect element;
forming a dielectric layer over the capping layer;
etching a contact hole and a via hole through the dielectric layer, wherein the contact hole partially exposes the first interconnect element, and wherein the via hole partially exposes the second interconnect element; and
filling the contact hole with a conductive contact and filling the via hole with a conductive via;
wherein the forming the conductive pad layer and the forming the capping layer are performed such that:
the first material composition include aluminum that is doped with copper, and the second material composition includes titanium nitride; or
the first material composition include aluminum that is doped with silicon or ruthenium, and the second material composition includes silicon oxynitride; or
the first material composition include aluminum that is doped with silicon or ruthenium, and the second material composition includes titanium nitride.

17. The method of claim 16, further comprising: forming a pixel over the conductive via.

18. The method of claim 16, wherein the capping layer is formed through a deposition process that is performed at a room temperature.

19. The method of claim 16, further comprising: after the patterning process is performed but before the dielectric layer is formed, forming a sidewall capping layer on a side surface of the conductive pad layer and on a side surface of the capping layer.

20. The method of claim 16, wherein:
the conductive pad layer is a first conductive pad layer;
the method further comprises forming a second conductive pad layer over the first conductive pad layer;
the capping layer is formed over the second conductive pad layer;
one of the first conductive pad layer and the second conductive pad layer includes aluminum doped with copper; and
another one of the first conductive pad layer and the second conductive pad layer includes aluminum doped with silicon or ruthenium.
